(19) United States
(12) Patent Application Publication
(10) Pub. No.: US 2008/0223700 A1
(43) Pub. Date: Sep. 18, 2008

(54) ELECTROSTATIC ACTUATOR

(75) Inventors: Sami Kotilainen, Niederrohrdorf (CH); Jan-Henning Fabian, Mellingen (CH); Ralf Struempler, Erding (DE)

Correspondence Address: BUCHANAN, INGERSOLL & ROONEY PC, POST OFFICE BOX 1404, ALEXANDRIA, VA, 22313-1404, US

(73) Assignee: ABB RESEARCH LTD, Zurich (CH)

(21) Appl. No.: 12/128,150

(22) Filed: May 28, 2008

Related U.S. Application Data
(63) Continuation of application No. PCT/CH2005/000702, filed on Nov. 28, 2005.

(51) Int. Cl. H01H 59/00; H01L 21/3065

(52) U.S. Cl. 200/181; 438/52; 257/415; 257/E21.218

(57) ABSTRACT

An actuator comprising a movable electrode and a static electrode is disclosed. An exemplary actuator is actuateable using an electrical potential difference that is applied between the movable electrode and the static electrode. The actuator comprises static bridge contacts with conductive surfaces, and a contact area with a conductive surface facing said bridge contacts located on the movable electrode. An electrically conductive contact is established between the bridge contacts, when the movable electrode contacts the static electrode. The movable electrode comprises at least two elements, a first element and a second element. The second element is movable with respect to the first element.

### RELATED APPLICATION

This application claims priority as a continuation application under 35 U.S.C. §120 to PCT/CH2005/000702 filed as an International Application on Nov. 28, 2005 designating the U.S., the entire content of which is hereby incorporated by reference in its entirety.

### TECHNICAL FIELD

The invention relates to the field of electrostatic actuators, especially to micro-electromechanical (MEMS) actuators.

### BACKGROUND INFORMATION

In the field of micro-electromechanical actuators, the problem arises, that micro-electromechanical actuators of prior art require high actuation or snap-in voltage to be actuated.

Furthermore the design of such actuators is not very efficient in terms of the spatial design (i.e. low voltage compared to surface area) therefore the costs of such actuators remain high. Due to the spatial design it is furthermore not possible to use electrostatic actuators in some areas of possible applications.

In addition to the already mentioned problems of prior art, such actuators comprise a complicated mechanical structure.

U.S. Pat. No. 6,911,891 discloses bistable actuation techniques, mechanisms and applications. The bistable structure comprises a deflection element, which has mechanically constrained end points and a compliant span between the end points. Thereby the bistable structure, also designated as deflection element, is able to deflect between two stable positions. The bistable structure may comprise a plurality of electrically conductive relay contacts, in order to provide an electrical connection, when the deflection element is in one of the two stable positions. The deflection element has to be actuated by a force generating actuator. The force generating actuator receives an electrical stimulus for applying the force to the bistable structure.

This has been the drawback that the mechanical structure of the deflection element is rather complicated. This complicated structure increases the cost for the manufacturing process and is inefficient regarding the spatial design.

It is a further drawback that due to the stiffness of the deflection element the actuation force remains rather high. Thus a high voltage is required to actuate the deflection element.

In addition it is a disadvantage that due to the external actuators and the bistable structure of the above mentioned mechanism the spatial design is very inefficient as well as due to fact that generally two deflection elements are used.

Furthermore it is a drawback in some applications that the structure is bistable and therefore the actuator has to actuate the deflection element in two directions in order to change the switching status of the deflection element.

The publication “Drie-Fabricated curved-electrode zipping actuators with low pull-in voltage”, which was published in DRIE-fabricated curved-electrode zipping actuators with low pull-in voltage Jian Li; Brenner, M. P.; Lang, J. H.; Slocum, A. H.; Struempler, R.; TRANSDUCERS, Solid-State Sensors, Actuators and Microsystems, 12th International Conference on, 2003 Volume 1, 8-12 Jun. 2003 Page(s):480-483 vol. 1 discloses the other concept of an actuator. Thereby the actuator comprises an actuator cantilever, a starting cantilever and an electrode. An electric potential difference may be applied to the actuator cantilever and to the electrode, due to the electrical field, the cantilever bends towards the electrode and contacts the electrode in a rolling manner in a so-called zipping motion. However this publication does not disclose an industrial application like an actuator.

### SUMMARY

Exemplary embodiments disclosed herein can provide an electrostatic actuator that requires a lower actuation voltage.

Additionally, exemplary embodiments disclosed herein can provide an actuator with a more efficient spatial design and therefore allowing less cost-intensive production and higher miniaturization.

An actuator is disclosed comprising a movable electrode and a static electrode, which is actuateable using an electrical potential difference that is applied between the movable electrode and the static electrode, wherein the actuator comprises static bridge contacts with conductive surfaces, and a contact area with a conductive surface located on the movable electrode and facing said bridge contacts, wherein an electrically conductive contact is established between the bridge contacts, when the movable electrode contacts the static electrode, wherein the movable electrode comprises at least two elements, a first element which is an upper cantilever and a second element which is a lower cantilever, wherein said second element is movable with respect to said first element and wherein the lower cantilever is located below the upper cantilever if the actuator is in its relaxed position.

### BRIEF DESCRIPTION OF THE DRAWINGS

The drawings will be explained in greater detail by means of a description of an exemplary embodiment, with reference to the following figures:

FIG. 1 shows a schematic view of an actuator of a first generation;

FIG. 2 shows a schematic view of an actuator of a second generation;

FIG. 3 shows a schematic view of an actuator according to an exemplary embodiment of the present disclosure with a very low actuation voltage;

FIG. 4 shows a first exemplary embodiment according to the present disclosure with a beam-like structure in vertical view;

FIG. 5 shows the embodiment of FIG. 1 in profile;

FIG. 6 shows a second exemplary embodiment according to the present disclosure with a stacked structure; and

FIG. 7 shows a third exemplary embodiment according to the present disclosure with two bearing points.

### DETAILED DESCRIPTION

An exemplary actuator comprises a movable, in particular flexibly deflectable, electrode and a static electrode. The actuator is actuateable using an electrical potential difference that is applied between the movable electrode and the static electrode. Moreover the actuator comprises static bridge contacts, with conductive surfaces, and a contact area with a conductive surface located on the movable electrode and facing the bridge contacts.

One of the key features of the disclosure is the fact that the actuator is an inverted actuator beam, allowing reduction of the actuation voltage. The actuator is able to establish an electrically conductive contact between the bridge contacts when the movable electrode contacts the static electrode. The movable electrode comprises at least two elements, a first element and a second element. The second element is movable, in particular flexibly deflectable, with respect to the first element. This provides a flexible structure with an efficient spatial design. Furthermore this actuator requires a low actuation force to be actuated. In addition it is possible that both bridge contacts are contacted by the movable electrode simultaneously, since the movable electrode is preferably parallel to the bridge contacts.

The first element of the movable electrode is usually attached to a static attachment point and the second element of the movable electrode establishes contact to the static electrode.

The contact area is preferably located close to or at a connecting element connecting the first and the second element.

The first element of the actuator according to the present disclosure is preferably an upper cantilever of the movable electrode and the second element is a lower cantilever of the movable electrode. Preferably the lower cantilever is parallel to and located below the upper cantilever if the actuator is in its relaxed position.

According to another exemplary embodiment of the present disclosure, the static electrode comprises a zipping surface that is tilted with respect to a surface, which is located on the lower cantilever of the movable electrode in its relaxed position. The arrangement is preferably such, that the distance between the static electrode and the movable electrode is progressively increasing towards the bridge contacts.

The movable electrode according to a further exemplary embodiment of the present disclosure comprises a first cantilever and a second cantilever. A first end of the first cantilever is rigidly connected to an attachment point. A second end of the first cantilever is connected to a first end of the connecting beam. The second cantilever is connected to an other end of the connecting beam. A surface of the second cantilever contacts with the surface of the static electrode, when the actuator is actuated. The first cantilever, the connecting beam and the second cantilever form a structure that is U-shaped. It is an advantage, that this structure has a low stiffness and is thus very flexible. Furthermore it is very efficient in terms of the spatial design. However it is also possible that the connecting beam is designed rather short, that only a rather small slot divides the upper cantilever from the lower cantilever.

The movable electrode of an actuator according to another exemplary embodiment of the present disclosure also comprises an upper cantilever, a middle cantilever and a lower cantilever. The upper cantilever is preferably rigidly attached to an attachment point and connected to the middle cantilever via a first connecting beam. The middle cantilever is connected to the lower cantilever via an opposite second connecting beam. Thereby a stacked structure results. When the actuator is actuated, a surface of the lower cantilever contacts with a surface of the static electrode. Compared to the U-shaped structure, the stiffness of the stacked structure becomes even lower. Thereby the actuation force, i.e. the actuation voltage to actuate the actuator, becomes smaller.

The stacked structure of the actuator may comprise even more than three cantilevers. The stacked structure will thus become even more flexible if it comprises more cantilevers. Therefore stacked structure preferably comprise between three and six cantilevers. It is also possible that the stacked structure comprises even more cantilevers.

In a further exemplary embodiment of the present disclosure, the movable electrode comprises mirror symmetric connected stacks of cantilevers. The mirror plane lies substantially between the bridge contacts and orthogonal to the cantilevers in their relaxed position. Furthermore this exemplary embodiment comprises two static electrodes. Due to the length of the cantilever, the structure becomes even more flexible and therefore requires less actuation force, which also means that it requires a lower actuation voltage.

The actuator or switch according to the present disclosure is monostable. In contrast to a bistable actuator, this actuator is, as already mentioned, monostable and has to be actuated in one direction only, in order to change its status. The contact remains open as long as the electric potential difference is lower than a first threshold voltage or snap in voltage, and the contact remains established only as long as the electric potential difference is higher than a second threshold voltage or snap out voltage. Preferably the first threshold voltage or snap in voltage is at least 5 Volts. Preferably the threshold voltage is between 5 and 50 Volts. Very good results were achieved with a threshold voltage from 5 to 20 Volts. Typically the second threshold voltage or snap out voltage is lower than the snap in voltage. Furthermore the arrangement as described above may ensure that the electrodes are contacted simultaneously.

The movable electrode as well as the static electrode are made of materials that are generally known as micromachinable materials. However the material must be electrically conductive or at least slightly electrically conductive. Good results were achieved with a bulk resistivity of less than 50 kOhm cm. Very good results were achieved with a silicon that shows a resistivity 0.1 to 0.01 Ohm cm. Furthermore it is possible to use standard MEMS materials such as crystalline silicon, p- or n-doped crystalline silicon, polysilicone and (doped) quarz as well as other metallic materials (e.g. electroplated metals as e.g. Ni, Cu or Au).

The movable electrode according to the exemplary embodiments of the present disclosure is preferably made out of one single piece. Even more preferably, the actuator is fabricated out of at least one single piece. This allows efficient manufacturing steps and reduces costs of the manufacturing process.

The conductive surfaces are coated with an electrically conductive material which is preferably an evaporated, sputtered or electroplated metal. The material may be chosen from the group of Au, Ag and Pd. If the relay is operated under inert gas atmosphere also Rh, Ru or Cu are possible. Furthermore, various alloys are used as a standard material for electrical contacts and are also suited for the relay application: Ag alloys as AgC3-10; Au alloys as AuPt10, AuAg8, AuAg25Pt6, AuAg20-30, AuNi5, AuAg26ni3; Pd alloys as AgPd30-60, Pt alloys as PtW5, PtNi8.

The actuator comprises several typically crucial dimensions. A distance X between the surface of the lower cantilever and the surface of the static electrode is preferably between 10 μm and 40 μm. However this distance may also even smaller than 10 μm. The cantilever structure comprises a length Y that is preferably between 100 μm and 3000 μm. If the length Y is chosen to be longer, the force required to actuate the actuator becomes lower and if the length Y is chosen smaller the actuation force is higher. The cantilevers furthermore comprise a thickness Z that is between 10 μm and 40 μm. Another characteristic dimension is the angle α which is the angle of the surface of the static electrode in respect to the cantilever. Thereby the angle α is preferably between 1° and 20°. Furthermore the third dimension plays also a crucial role. A dimension W describes the thickness of the structure. The width W is preferably between 20 μm and wafer thickness. The actuation voltage depends basically on the length Y, on the distance X, on the thickness Z and on the width W. With the mentioned dimensions there is provided an actuator that has a very low stiffness, which leads to a low actuation voltage or snap-in voltage. However, depending on the application other dimensions, which are smaller or larger, are also possible.

A further crucial characteristic of the actuator is the fact that the smallest gap between the moveable electrode and the static electrode is arranged at a point, where the structure of the moveable electrode has the highest degree of flexibility. This means that the lowest possible force for first contact between the moveable and static electrode is required to move the moveable electrode.

According to the present disclosure, there is furthermore provided a method to manufacture such an actuator. Thereby a deep reactive ion etching method (DRIE) is used in at least one manufacturing step.

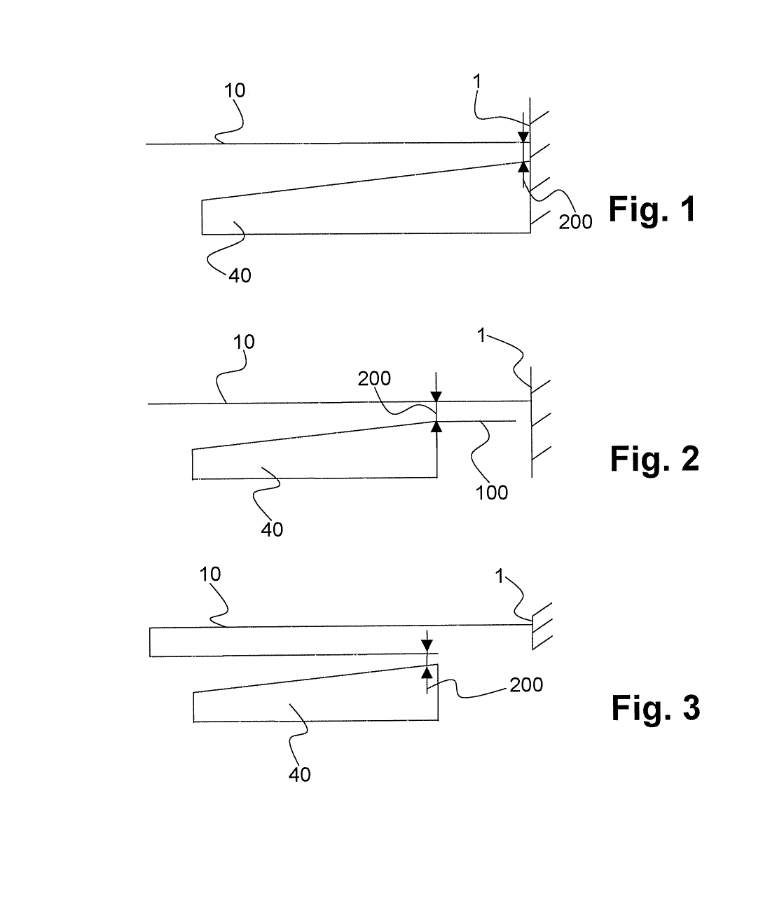

Referring to the drawings, which are for the purpose of illustrating the present exemplary embodiments of the disclosure and not for the purpose of limiting the same, FIG. 1 shows an actuator of the first generation as it is known. The actuator comprises a moveable electrode 10 and a static electrode 40. Bridge contacts are not shown in this schematic figure. To actuate this arrangement an electric potential difference, as it is described in more detail further on, has to be applied to the moveable electrode 10 and to the static electrode 40. During the step of being actuated the moveable electrode 10 contacts the static electrode 40 at first where the gap between the moveable electrode 10 and the static electrode 40 is at its smallest. This gap is designated as smallest gap 200. It is a drawback of this arrangement, that the smallest gap 200 is arranged there, where the highest mechanical force is required to move the moveable electrode 10. Due to this fact a high actuation voltage is required. The actuation voltage is typically between 80 and 140 Volts. As soon as the first contact is established, the moveable electrode 10 contacts the static electrode 40 in a rolling or zipping manner.

FIG. 2 shows an actuator according to a second generation. A compliant starting zone 100 makes it possible that the point, where the first contact between the moveable electrode 10 and the static electrode 40 is being made, is arranged in a section, where the actuation force is smaller than as described by means of FIG. 1. However the actuation voltage remains relatively high.

FIG. 3 shows schematically an actuator according to an exemplary embodiment of the present disclosure. Due to the fact that the smallest gap 200 occurs at the most compliant or flexible part of the moveable electrode 10 it is possible to reduce the actuation voltage dramatically.

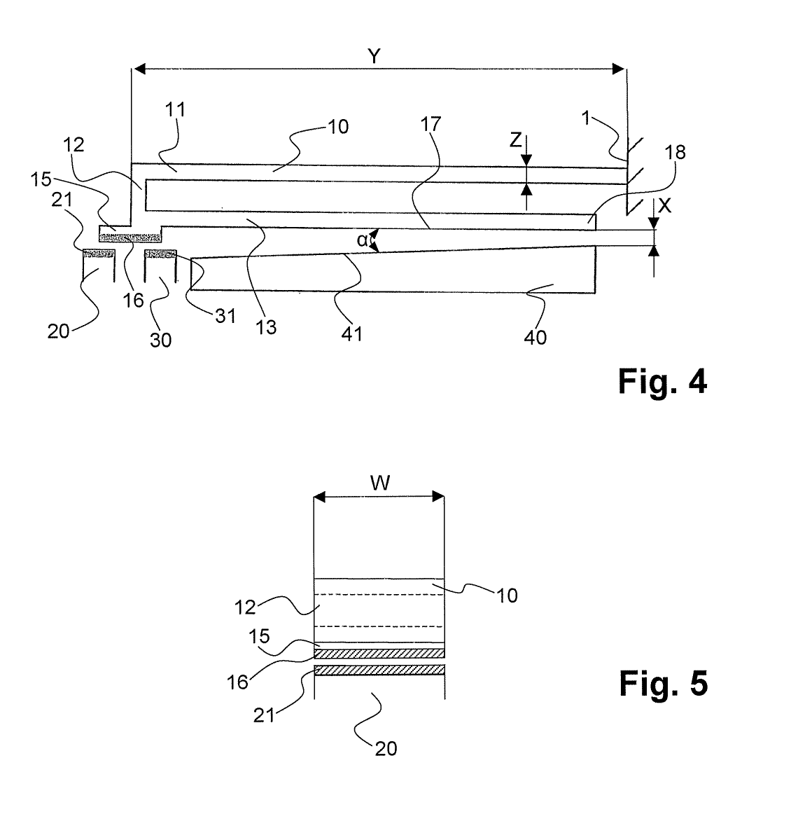

FIG. 4 shows a first exemplary embodiment according to the present disclosure. Thereby the actuator comprises a movable electrode 10, a first bridge contact 20, a second bridge contact 30 and a static electrode 40.

The purpose of this disclosure is to lower the actuation or the snap in voltage of an electrostatic relay. The relay disclosure described here is monostable and therefore requires the actuation voltage to be applied continuously, when the relay is in the closed state.

The disclosure comprises a single or multiple stationary electrode(s) and a single moving electrode, which is shaped like a beam. The beam may also be described as inverted actuator beam. This due to the fact that the snap in or actuation voltage is proportional to 1/X̂2 and the beam stiffness to 1/Ŷ3. The dimensions X and Y will be defined later on. The tip or free end of the beam is close to the fixed electrode. As the potential is applied between the beam (movable electrode) and the fixed electrode the tip or free end will snap into a contact with the fixed electrode as the voltage will cross the first threshold voltage, also designated as snap-in voltage. After the snap-in the beam rolls along the fixed electrode closing the electrical contacts and providing the necessary contact force. In order to fix the moving parts of the relay another beam is folded over the beam that comes into contact with the fixed electrode. This beam can also be very flexible, thus further reducing the snap-in voltage without having contact-force reducing effect.

The movable electrode 10 comprises an upper cantilever 11, a connecting beam 12, a lower cantilever 13 and a contact area 15. Thereby the upper cantilever 11 and the lower cantilever 13 are movable with respect to each other via the connecting beam 12. One end of the upper cantilever 11 is connected to an attachment point 1, which is statically arranged in respect with the movable electrode 10. Said connection is rigid. The other end of the upper cantilever 11 is connected to one end of the connecting beam 12. Thereby the connecting beam 12 lies orthogonal to the upper cantilever 11. One end of the lower cantilever 13 is connected to the other end of the connecting beam 12. Thereby the lower cantilever 13 lies also orthogonal to the connecting beam 12. This means that the upper cantilever 11 and the lower cantilever 13 are substantially parallel in the relaxed position. The cantilevers are thus arranged in a manner that an U-shaped structure results with one free end and one attached end. The other end of the lower cantilever 13 is nonattached, this end is also designated as free end 18. The surface located on the lower cantilever 13 and facing towards the fixed electrode is designated as surface 17. The surface 17 is coated with a contact metallization. Before applying the contact metallization, the complete structure is passivated by the deposition of an electric insulation layer. Typical passivation layers are Silicon Oxide SiO₂ or Silicon Nitride Si₃Ni₄. SiO₂ is deposited in a chemical vapour deposition (CVD) process or thermally grown; Si₃Ni₄ is for such applications generally deposited in a CVD process.

The contact area 15 is arranged in the area of the connecting beam 12. The surface of the contact area 15 is coated with a conductive film 16 that is able to conduct an electrical current. The coating material may be Ag, Au and is applied by sputtering, vapor deposition, electroplating or a combination of these processes, such as, e.g., sputtering as well as vapor desposition can be followed by electroplating.

The two bridge contacts 20, 30 are also coated with an electrically conductive film 21, 31. The bridge contacts 20, 30 are arranged in a way that their contact surfaces 21, 31 are coplanar, which may also be designated as contact plane. Both, the bridge contact 20 and the bridge contact 30 are arranged statically.

The static electrode 40 comprises a zipping surface 41, which is tilted with respect to the surface 17 of the movable electrode 10. The static electrode 40 is static in view of the movable electrode 10. Letter X designates the minimal distance between the tilted zipping surface 41 and the free end 18 of the second cantilever 13. This distance may also be designated as gap distance or smallest gap. The zipping surface 41 then extends along the static electrode 40 in direction to the bridge contacts 20, 30, whereby the distance to the second cantilever 13 is constantly increasing.

Further characteristic dimensions are the length Y of the movable electrode 10 and the thickness Z of the cantilevers. Very good results were achieved, e.g., with a length Y between 100 μm and 2000 μm or 3000 μm and, in particular, with a thickness Z between 10 μm and 40 μm and, in particular, in combination with a distance X between 10 μm and 40 μm, and, in particular, with a width W between 20 μm and wafer thickness.

For the sake of completeness: the static electrode 40, the first bridge contact 20, the second bridge contact 30 and the attachment point 1 are arranged in a static manner with respect to each other and may also be designated as static arrangement. The movable electrode 10 is movable with respect to the static arrangement. This means that the movable electrode 10 is movable with respect to the static arrangement.

As soon as an electric potential difference is applied to the movable electrode 10 and to the fixed electrode 40 an electrical field is generated. As soon as the electrical field crosses a first threshold voltage, the free end 18 of the lower cantilever 13 moves towards the fixed electrode 40. In a first step, the surface 17 of the lower cantilever 17 contacts thereby the zipping surface 41 with the free end 18. Thereby the distance between the movable electrode 10 and the fixed electrode 40 decreases continuously. As a consequence thereof, the movable electrode establishes contact over the whole length in a rolling or zipping manner.

When the contact is established over substantially the whole length of the zipping surface 41, the conductive surface 16 of the movable cantilever 10 contacts the conductive surface 21 of the first bridge contact 20 and the conductive surface 31 of the second bridge contact 30. Thereby an electrically conductive contact is established between the two bridge contacts 20, 30.

The electrically conductive contact remains established as long as the applied electric potential difference is higher than a second threshold voltage or snap out voltage. If the electrical potential difference becomes lower than the second threshold voltage, the movable cantilever returns to its initial position.

FIG. 5 shows the exemplary embodiment of FIG. 4 in profile. It can be seen that the width W describes the distance that is formed from one edge of the moveable electrode 10 to the other edge of the moveable electrode 10.

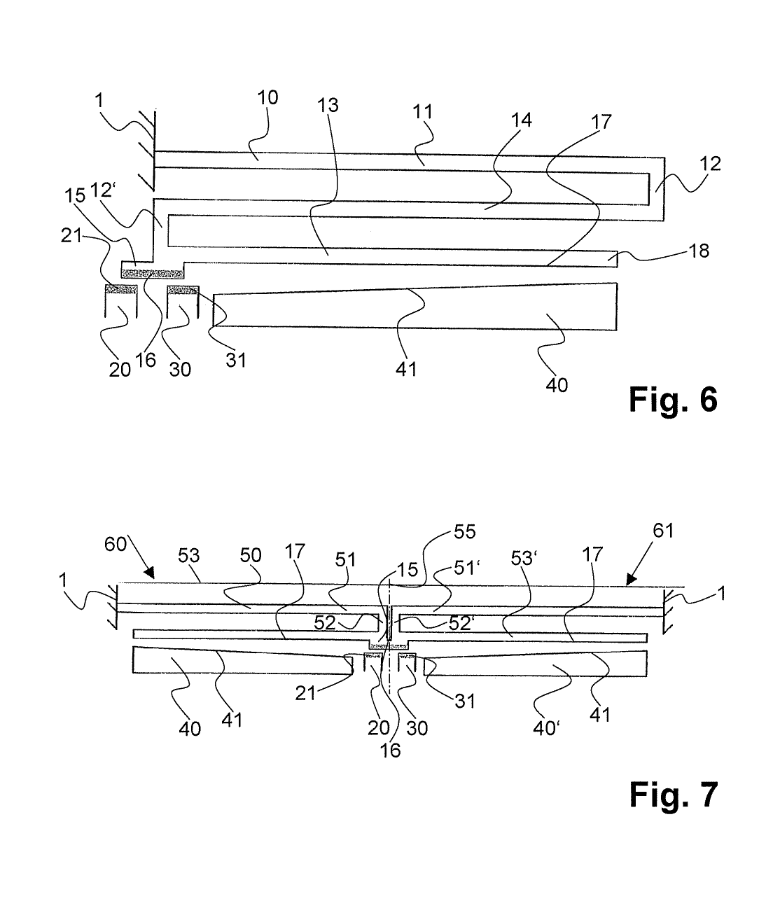

FIG. 6 shows a further exemplary embodiment according to the present disclosure.

In this exemplary embodiment, the movable electrode 10 comprises an upper cantilever 11, connecting beams 12,12′, a lower cantilever 13, a middle cantilever 14 and a contact area 15. The upper cantilever 11, the lower cantilever 13 and the middle cantilever 14 are movable, i.e. flexibly deflectable, with respect to each other. One end of the upper cantilever 11 is connected to the attachment point 1, which is statically arranged as described above. The other end of the upper cantilever 11 is connected to one end of a first connecting beam 12. The first connecting beam 12 is orthogonal to the upper cantilever 11. One end of the middle cantilever 13 is connected to the other end of the first connecting beam 12. The middle cantilever 14 is also orthogonal to the first connecting beam 12. On the other end of the middle cantilever 14 there is a second connecting beam 12′ attached. This second connecting beam 12′ is arranged orthogonal to the middle cantilever 14. At the other end of the second connecting beam 12′ there the lower cantilever 13 is attached. The lower cantilever 13 is also orthogonal to the second connecting beam 12′. This means that the upper, the middle and the lower cantilever are substantially parallel and the cantilevers are arranged in a manner that a stacked structure results. The other end of the lower cantilever is nonattached, this end is also designated as free end 18. The surface located on the lower cantilever 13 and facing towards the fixed electrode is designated as surface 17.

The static electrode 40 as well as the first bridge contact 20 and the second bridge contact 30 are arranged in the same way as in the first exemplary embodiment.

The switching operation is identical as described above. However this exemplary embodiment requires an even lower actuation force as the first exemplary embodiment. Therefore the electric potential difference, i.e. actuation voltage or snap-in voltage, can be lower.

Additionally it is possible that the stacked structure may comprise even more cantilevers as in the second exemplary embodiment. With an increasing number of cantilevers, the stiffness of the structure decreases. For that reason the actuation force decreases too, which means that a lower actuation voltage is required.

FIG. 7 shows a further exemplary embodiment according to the present disclosure. Thereby the whole arrangement as described in the first exemplary embodiment is arranged mirrorsymmetrically. The mirror plane, indicated by line 55, lies between the first bridge contact 20 and the second bridge contact 30 and is orthogonal to the upper cantilever in its relaxed position.

The movable electrode 50 thereby comprises a left side 60 and a right side 61, both of which include an upper cantilever 51, 51′, a connecting beam 52, 52′ and a lower beam 53, 53′. The cantilevers 51, 51′, 53, 53′ are arranged in the same way as described above. The ends of the upper cantilevers 52, 52′ are attached to the attachment points 1. The contact area 15 is designed as linker element between the left side 60 and the right side 61 of the movable electrode 50. As described above, the contact area 15 is coated with an electrically conductive surface 16.

Furthermore the third exemplary embodiment comprises two fixed electrodes 40, 40′, which are also mirror symmetrically arranged. The function as well as the design are equal to the above mentioned exemplary embodiments.

The switching operation is the same as described above. Nevertheless it has to be mentioned that due to the long span of the movable electrode 50 the stiffness is lowered in comparison to the first exemplary embodiment.

These actuators or relays could be fabricated using Microsystems technology, namely by an ICP process called DRIE (Deep Reactive Ion Etching), wherein the material of the relay is Silicon with appropriate layers on the electrical contacts and current paths. The structure is formed in the plane of the wafer as opposed to surface micro-machining, wherein the structure stands on top of the wafer plane. Preferably the relays or actuators are made out of a single wafer.

It will be appreciated by those skilled in the art that the present invention can be embodied in other specific forms without departing from the spirit or essential characteristics thereof. The presently disclosed embodiments are therefore considered in all respects to be illustrative and not restricted. The scope of the invention is indicated by the appended claims rather than the foregoing description and all changes that come within the meaning and range and equivalence thereof are intended to be embraced therein.

### LIST OF REFERENCE NUMERALS

1 attachment point
10 movable electrode
11 upper cantilever
12 connecting beam
13 lower cantilever
14 middle cantilever
15 contact area
16 conductive surface
17 contact surface
20 first bridge contact
21 conductive surface
30 second bridge contact
31 conductive surface
40 static electrode
41 zipping surface
50 meander shaped movable electrode
51, 51′ upper cantilevers
52, 52′ connecting beam
53, 53′ lower cantilevers
54 gap
55 symmetry axis
60 left side
61 right side
100 compliant starting zone
200 smallest gap

What is claimed is:

1. An actuator comprising:
a movable electrode and a static electrode, which is actuateable using an electrical potential difference that is applied between the movable electrode and the static electrode;
static bridge contacts with conductive surfaces; and
a contact area with a conductive surface located on the movable electrode and facing said bridge contacts, wherein an electrically conductive contact is established between the bridge contacts, when the movable electrode contacts the static electrode, wherein the movable electrode comprises at least two elements, a first element which is an upper cantilever and a second element which is a lower cantilever, wherein said second element is movable with respect to said first element and wherein the lower cantilever is located below the upper cantilever if the actuator is in its relaxed position.

2. Actuator according to claim 1, wherein the first element of the movable electrode is attached to a static attachment point, and wherein the second element of the movable electrode establishes contact to the static electrode.

3. Actuator according to claim 1, wherein said contact area is located close to or at a connecting element connecting said first and said second element.

4. Actuator according to claim 1, wherein the lower cantilever is substantially parallel to the upper cantilever, if the actuator is in its relaxed position.

5. Actuator according to claim 4, wherein the static electrode comprises a zipping surface that is tilted with respect to a surface of the lower cantilever of the movable electrode, the distance between the static electrode and the movable electrode progressively increasing towards the bridge contacts in the relaxed position.

6. Actuator according to claim 4, wherein the movable electrode comprises a first cantilever, which has a first end that is rigidly connected to an attachment point and a second end that is connected to a first end of a connecting beam, and a second cantilever that is connected to an other end of the connecting beam, and wherein a surface of the second cantilever contacts with the zipping surface of the static electrode, when actuated.

7. Actuator according to claim 4, wherein the movable electrode comprises an upper cantilever, a middle cantilever and a lower cantilever, wherein the upper cantilever can be rigidly connected to an attachment point and the upper cantilever is connected to the middle cantilever via a first connecting beam and the middle cantilever is connected to the lower cantilever via an opposite second connecting beam so that a stacked structure results, and wherein a surface of the lower cantilever contacts with the zipping surface of the static electrode, when actuated.

8. Actuator according to claim 7, wherein the stacked structure comprises more than three cantilevers.

9. Actuator according to the claim 4, wherein the movable electrode comprises two mirror symmetric connected stacks of cantilevers, whereby the mirror plane substantially lies between the bridge contacts and orthogonal to the cantilevers in its relaxed position, and wherein two static electrodes are arranged.

10. Actuator according to claim 1, wherein the actuator is monostable and the contact remains open as long as the electric potential difference is higher than a first threshold voltage, and the contact remains established only as long as the electric potential difference is lower than a second threshold voltage, whereby the second threshold voltage can be lower than the first threshold voltage and the first threshold voltage is preferably at least 5 Volts.

11. Actuator according to claim 1, wherein the movable electrode and the static electrode are made of micromachinable materials, such as crystalline silicon, p- or n-doped crystalline silicon, polysilicone, (doped) quarz or metallic materials.

12. Actuator according to claim 1, wherein conductive surfaces are coated with an electrically conductive material chosen from the group of Au, Ag, Pd, Pt or mixtures, combinations and/or alloys thereof, or if the relay is operated under inert gas atmosphere, chosen from the group of Rh, Ru, Cu or mixtures, combinations and/or alloys thereof.

13. Actuator according to claim 4, wherein a distance between the surface of the lower cantilever and the zipping surface of the static electrode is preferably between 10 μm and 40 μm, and/or wherein the cantilever structure comprises a length that is preferably between 100 μm and 3000 μm, and/or wherein the cantilevers comprise a thickness that is between 10 μm and 40 μm, and/or wherein the angle (α) of the zipping surface of the static electrode in respect to the lower cantilever or cantilevers is between 1° and 20°, and/or wherein a width of the moveable electrode is between 20 μm and wafer thickness.

14. Actuator according to claim 1, wherein the smallest gap between the moveable electrode and the static electrode is arranged at a point where the structure of the moveable electrode has the highest degree of flexibility.

15. Method for manufacturing an actuator according to claim 1, wherein a deep reactive ion etching method (DRIE) is used in at least one manufacturing step.

16. Actuator according to claim 2, wherein said contact area is located close to or at a connecting element connecting said first and said second element.

17. Actuator according to claim 1, wherein the lower cantilever is substantially parallel to the upper cantilever, if the actuator is in its relaxed position.

18. Actuator according to claim 5, wherein the movable electrode comprises a first cantilever, which has a first end that is rigidly connected to an attachment point and a second end that is connected to a first end of a connecting beam, and a second cantilever that is connected to an other end of the connecting beam, and wherein a surface of the second cantilever contacts with the zipping surface of the static electrode, when actuated.

19. Actuator according to the claim 8, wherein the movable electrode comprises two mirror symmetric connected stacks of cantilevers, whereby the mirror plane substantially lies between the bridge contacts and orthogonal to the cantilevers in its relaxed position, and wherein two static electrodes are arranged.

20. Actuator according to claim 9, wherein the actuator is monostable and the contact remains open as long as the electric potential difference is higher than a first threshold voltage, and the contact remains established only as long as the electric potential difference is lower than a second threshold voltage, whereby the second threshold voltage can be lower than the first threshold voltage and the first threshold voltage is preferably at least 5 Volts.

20. Actuator according to claim 10, wherein the movable electrode and the static electrode are made of micromachinable materials, such as crystalline silicon, p- or n-doped crystalline silicon, polysilicone, (doped) quarz or metallic materials.

21. Actuator according to claim 11, wherein conductive surfaces are coated with an electrically conductive material chosen from the group of Au, Ag, Pd, Pt or mixtures, combinations and/or alloys thereof, or if the relay is operated under inert gas atmosphere, chosen from the group of Rh, Ru, Cu or mixtures, combinations and/or alloys thereof.

22. Actuator according to claim 12, wherein a distance between the surface of the lower cantilever and the zipping surface of the static electrode is preferably between 10 μm and 40 μm, and/or wherein the cantilever structure comprises a length that is preferably between 100 μm and 3000 μm, and/or wherein the cantilevers comprise a thickness that is between 10 μm and 40 μm, and/or wherein the angle (α) of the zipping surface of the static electrode in respect to the lower cantilever or cantilevers is between 1° and 20°, and/or wherein a width of the moveable electrode is between 20 μm and wafer thickness.

23. Actuator according to claim 13, wherein the smallest gap between the moveable electrode and the static electrode is arranged at a point where the structure of the moveable electrode has the highest degree of flexibility.

24. Method for manufacturing an actuator according to claim 14, wherein a deep reactive ion etching method (DRIE) is used in at least one manufacturing step.
